(19) United States
(12) Patent Application Publication
(10) Pub. No.: US 2006/0183321 A1
(43) Pub. Date: Aug. 17, 2006

(54) Method for reduction of gap fill defects

(76) Inventor: Bulent M. Basol, Manhattan Beach, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/238,886

(22) Filed: Sep. 27, 2005

Related U.S. Application Data
(60) Provisional application No. 60/613,803, filed on Sep. 27, 2004.

(51) Int. Cl. H01L 21/44

(52) U.S. Cl. 438/653

(57) ABSTRACT

A method of electrodepositing a conductor to form a defect-free conductor layer on a wafer surface including features. The wafer surface including the features is lined with a nucleation film. The conductor is electrodeposited onto the nucleation layer from a process solution having an additive that adsorbs strongly on the already deposited conductor and weakly on the exposed portions of the nucleation layer. As a result, the conductor selectively deposits on the still exposed portions of the nucleation layer and covers them with the conductor, thereby forming the defect-free conductor layer on the wafer surface.

### RELATED APPLICATION

This application claims priority to U.S. Provisional Application No. 60/613,803, filed on Sep. 27, 2004, the entire disclosure of which is hereby incorporated herein.

### FIELD

The present invention generally relates to semiconductor integrated circuit technology and, more particularly, to an electroplating process and apparatus.

### BACKGROUND

Conventional semiconductor devices generally include a semiconductor substrate, usually a silicon substrate, and a plurality of sequentially formed dielectric layers and conductive paths or interconnects made of conductive materials. Interconnects are usually formed by filling a conductive material in trenches and vias etched into the dielectric layers. In an integrated circuit, multiple levels of interconnect networks laterally extend with respect to the substrate surface. Interconnects formed in different layers can be electrically connected using filled vias or contacts.

The filling of a conductive material into features, such as vias or trenches to form lines, pads or contacts, can be carried out by electrodeposition. In an electrodeposition or electroplating method, a conductive material, such as copper, is deposited over a substrate surface, including into such features. Then, a material removal technique is employed to planarize and remove the excess metal or overburden from the top surface of the substrate, leaving conductors only in the features or cavities. The standard material removal technique that is most commonly used for this purpose is chemical mechanical polishing (CMP). Chemical etching, electropolishing, which is also referred to as electroetching or electrochemical etching, and electrochemical mechanical polishing or etching are also attractive process options for copper removal. Copper is the material of choice, at this time, for interconnect applications because of its low resistivity and good electromigration properties.

Before filling copper into the features, the features are lined with a barrier layer, such as tantalum (Ta) or tantalum-nitride (TaN), or a bi-layer (Ta/TaN) including both Ta and TaN. After the barrier layer deposition, a copper seed is deposited using a chemical vapor deposition (CVD) or physical vapor deposition (PVD) process, typically by a PVD process. The copper seed layer is a thin film and allows copper to nucleate and grow on it during a subsequent deposition process. Electrodeposited copper cannot nucleate and grow properly on the standard Ta/TaN barrier layers; therefore, a seed layer is essential in copper electrodeposition. However, a seed layer deposition process must ensure a continuous coverage of the seed layer over the substrate, including on the internal surfaces of narrow features. Since the electroplated copper requires a copper seed layer for proper nucleation and growth, any discontinuity in the copper seed layer results in defects, such as holes or voids, in the electroplated copper within narrow features.

FIGS. 1A and 1B exemplify the formation of such a plating defect or fill defect during filling of a narrow trench or via 10. The illustrated trench 10 is formed in a dielectric layer 12 having a top surface 14. The walls 16 and bottom 18 of the trench 10 as well as the surface 14 of the dielectric layer 12 are coated with a barrier layer 20. A seed layer 22 is deposited onto the barrier layer 20. As shown in FIG. 1B, the illustrated seed layer 22 includes two exemplary discontinuities or defects 24 where no seed layer is deposited or the deposited thickness is so small that conductivity at those regions is not adequate and the copper is discontinuous. The defects 24, in effect, expose the underlying barrier layer 20 such that electrodeposited copper cannot nucleate and properly grow. This situation can be seen in FIG. 1B where an electrodeposited copper layer 26 can grow on the seed layer 22, but not on the defects 24, where portions of the barrier layer 20 are exposed. As the copper grows around the defects 24 in the seed layer 22, voids or holes 28 are formed in the copper layer 26, as shown in FIG. 1B. Such holes 28 increase the electrical resistance and reduces the reliability of the interconnect structure.

Therefore, there is a need for manufacturing processes and device structures to minimize or eliminate fill defects in interconnects originating from defective seed layers.

### SUMMARY

According to an aspect of the invention, a method is provided for electrodepositing a conductor to form a defect-free layer on a wafer surface including at least one cavity. The wafer surface including the at least one cavity is lined with a continuous conductive film. The conductor is electrodeposited onto the continuous conductive film from a process solution including at least one inhibiting additive configured to adsorb strongly on the conductor being electrodeposited and weakly on the continuous conductive film. The electrodepositing of the conductor forms a discontinuous layer exposing a surface portion of the continuous conductive film. A first concentration of the at least one inhibiting additive is adsorbed on the discontinuous layer while a second concentration of the at least one inhibiting additive is adsorbed on the exposed surface portion of the continuous conductive film. The first concentration of the at least one inhibiting additive is higher than the second concentration. Electrodepositing of the conductor continues, wherein the conductor electrodeposits on the surface portion of the continuous conductive film at a higher rate than on the discontinuous layer thus forming a defect-free layer.

According to another aspect of the invention, a method is provided for forming a defect-free conformal conductive layer coating a surface of a wafer surface including at least one cavity. The wafer surface includes the at least one cavity being lined with a nucleation layer. A conductive layer is electrodeposited onto the nucleation layer, wherein the conductive layer partially exposes a portion of the nucleation layer. A solution is applied onto the conductive layer and the portion of the nucleation layer. The solution includes at least one additive configured to adsorb strongly on the conductive layer and weakly on the nucleation layer. A first concentration of the at least one additive is adsorbed on the conductive layer while adsorbing a second concentration of the at least one additive on the portion of the nucleation layer. A conductor is electrodeposited on the conductive layer and the exposed portion of the nucleation layer to form a defect-free conformal conductive layer thereon, wherein the conductor electrodeposits on the portion of the nucleation layer at a higher rate than on the conductive layer.

According to yet another aspect of the invention, a method is provided for electrodepositing a conductor on a wafer surface having at least one cavity. The wafer surface is lined with a nucleation layer. A conductive layer is electrodeposited on the nucleation layer, wherein electrodepositing comprises applying a solution to the wafer surface. The solution comprises at least one suppressor or leveler configured to adsorb strongly on material of the conductive layer and weakly on material of the nucleation layer.

### BRIEF DESCRIPTION OF THE DRAWINGS

FIG. 1A is a schematic cross-sectional view of a portion of a substrate having a narrow trench having a barrier layer and a seed layer.

FIG. 1B is a schematic cross-sectional view of the portion of the substrate in FIG. 1A having defects in the seed layer after a prior art electrodeposition process.

FIG. 2 is a schematic cross-sectional view of an initial stage of filling a feature by electrodepositing a conductor, according to an embodiment.

FIG. 3 is a schematic cross-sectional view of a final stage of a feature filled with an electrodeposited conductor, according to an embodiment.

FIG. 4 is a schematic cross-sectional view of forming a defect-free conductive layer on a feature surface by electrodepositing a conductor on the features surface, according to an embodiment.

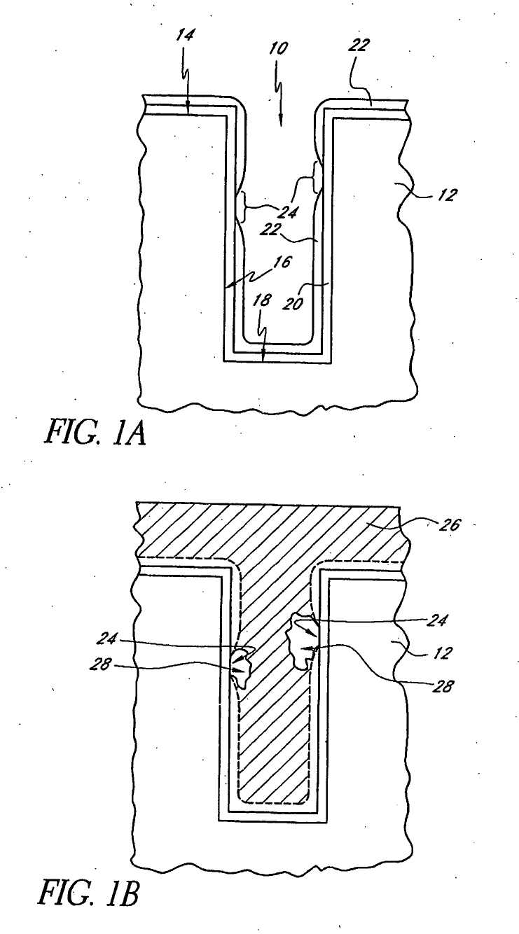

### DETAILED DESCRIPTION

Embodiments are described herein of a process that forms a nucleation layer over a barrier layer or replaces the barrier layer with a nucleation layer before a conductive layer, which may serve as a seed layer for a subsequent electroplating step, is directly electrodeposited on a wafer. The nucleation layer is selected from the group of materials that adheres well to the barrier layer or directly to the dielectric layer and has surface properties that allow good nucleation of electrodeposited copper. The nucleation layer can be a thin conductive material layer, such as a thin ruthenium (Ru) layer, W layer, Mo layer, MoN layer, WCN layer, or a layer of other materials on which copper can be electroplated with good adhesion. These layers may be deposited by methods, such as atomic layer deposition (ALD), which has the capability of depositing atomic layers of materials with excellent conformality and continuity. Forming a continuous nucleation layer on a wafer assures that the subsequently deposited conductive layer does not have defects or openings on the nucleation layer. Electrodeposited copper can grow on any exposed nucleation layer surface portions without forming voids or defects. In the embodiments described below, although copper deposition is exemplified, the process can be used in electrochemical deposition of any conductive material that employs a seed layer on which to deposit and grow.

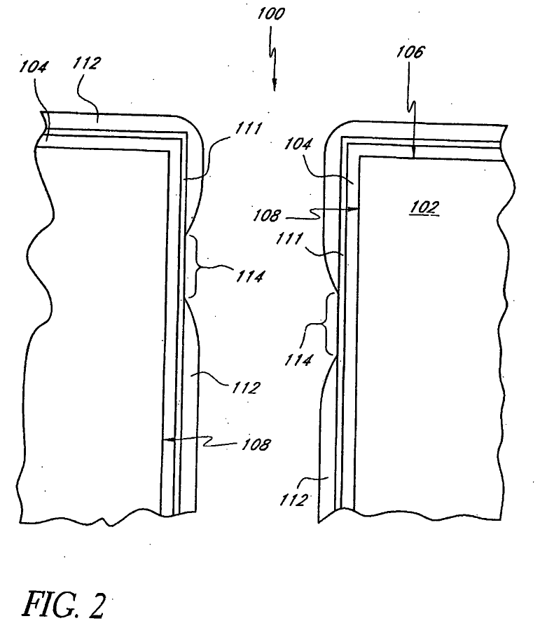

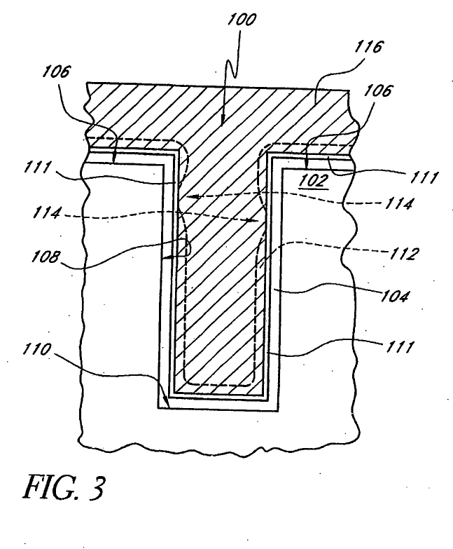

FIGS. 2 and 3, illustrate initial and final stages in filling a feature or cavity 100, such as a trench, by electrodepositing a conductor, preferably copper, according to an embodiment. The trench 100 may be formed in a dielectric layer 102, such as a low-k dielectric layer or an ultra low-k dielectric layer. The dielectric layer 102 can be a part of a surface of a semiconductor wafer (not shown). FIG. 2 shows an upper part or entrance of the trench 100 in an enlarged side view. A barrier layer 104 conformally covers a surface 106 of the dielectric layer 102 and the trench 100. Side walls 108 and the bottom 110 (FIG. 3) of the trench 100 are covered with the barrier layer 104. The barrier layer 104 is preferably a Ta/TaN layer, preferably having a thickness in the range of 50-200 angstroms (Å). A continuous nucleation film or layer 111 is formed on the barrier layer 104, using preferably a conformal deposition method, such as atomic layer deposition (ALD). In this embodiment, the nucleation film or layer 111 is preferably is made of ruthenium (Ru) or tungsten (W) metal. The thickness of the nucleation layer 111 is preferably in the range of about 5-50 Å, and more preferably about 20 Å.

Although, in this embodiment, the nucleation layer 111 is deposited onto the barrier layer 104, the nucleation layer 111, alternatively, can be deposited directly onto the dielectric layer 102. As mentioned above, the copper filling process of the trench 100 is performed, preferably using an electrodeposition process. Conventionally, in such processes, the wafer surface, including the above-exemplified trench 100, is placed in a deposition chamber. The chamber preferably includes an anode electrode immersed in a process solution, such as a plating electrolyte containing copper ions, acid, organic and inorganic additives. As the surface of the wafer is wetted by the solution, an electrical potential difference is applied between the wafer surface and the anode to fill the trench 100 and coat the surface of the wafer. When directly deposited on the dielectric layer, the nucleation film or layer 111 itself acts as the barrier layer and an additional barrier layer underneath can be omitted. The thickness of the directly deposited continuous nucleation film or layer 111 is preferably in the range of 50-500 Å to increase its conductance for the subsequent copper electroplating step. During the electroplating, as a conductive layer 112 (e.g., a copper layer) is being formed on the nucleation layer 111, openings 114, shown as open regions or discontinuities, may appear in the conductive layer 112, which expose the underlying nucleation layer 111. Such openings 114 are the regions on the nucleation layer 111 that are still not covered with the depositing conductor; therefore, the openings 114 are potential defect producing regions that should be eliminated by covering them with a depositing conductor. Very thin sections (high electrical resistance regions) in the conductive layer 112 may also be defect producing region. Although the openings 114 are shown to be on the side walls 108 of the trench 100, they may be anywhere within the trench 100, including the bottom 110 of the trench 100. Regardless, if the electrodeposition process continues after the opening 114 forms on the nucleation layer 111, the conductive layer 112 may continue growing in a non-uniform fashion and may close the entrance of the trench 100 or form a void around the opening 114. This non-uniform growing occurs because the conductive layer will tend to continue growing on the already deposited conductive layer 112 rather than the surface of the nucleation layer 111 exposed at the opening 114. As will be described more fully below, the electrodeposition process of the embodiments described herein provides defect free electrodeposited layers on the nucleation layers.

Note that electrodeposition can be conducted directly on the nucleation layer 111, such as Ru, and that openings can result during such direct electrodeposition. Openings can also result from depositing a seed layer, such as a PVD copper seed layer, over the nucleation layer 111 prior to electrodeposition. In either case, use of additives as described herein provides a self-healing mechanism to improve uniformity of electrodeposition (directly or indirectly) over the nucleation layer 111. Note also that, use of the additives over the nucleation layer improves uniformity in case any such openings exist or form during the process, and that the processes described herein do not depend upon the formation of such openings.

FIG. 3 shows a copper layer 116, which is electrodeposited using the process of a preferred embodiment. The copper layer 116 fills the trench 100 without holes or defects. In accordance with the principles of this embodiment, the process solution used includes inhibiting additives, such as suppressor and/or leveler molecules. The suppressor type chemicals are well-known in the copper electrochemical deposition field. Organic molecules, such as PEG, are used to hinder copper growth over surfaces where they are adsorbed by increasing the potential there. Organic suppressor additives are marketed by many companies under different labels. Such companies include Shipley and Enthone. For a low acid Enthone chemistry, for example, about 6 ml/l of suppressor additives may be used. Levelers are also like suppressors and they suppress growth at sites of the surface on which they become attached.

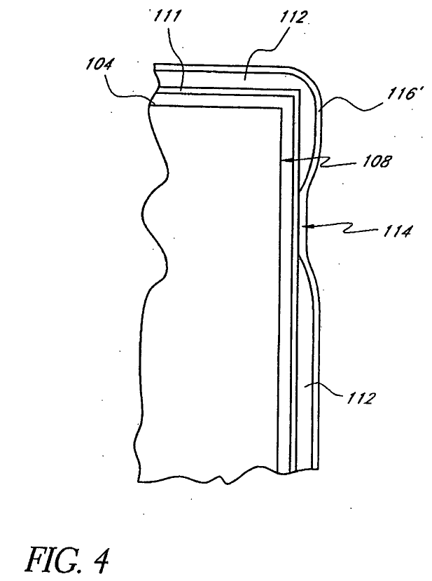

During the initial stage of the electrochemical deposition of the copper layer 116 on the structure shown in FIG. 3, the suppressor molecules are preferably adsorbed on the surface of the forming copper layer, but they do not adsorb well on the surface of the nucleation layer 111. The illustrated conductive layer 112, including exemplary openings 114, represents the initial deposition stage. As the initial conductive layer 112 is formed, the suppressors and/or levelers that are selected to adsorb strongly on the copper surface but not on nucleation layer surface, adsorb on the conductive layer 112 and increase polarization. Consequently, suppressor molecules are populated in greater numbers on the copper surface sites (high concentration of additive molecules) than the nucleation layer surface sites (low concentration of additive molecules). This is equivalent to formation of a high resistance surface layer on the surface of the conductive layer 112. If the polarization or the resistance of this high resistance surface layer is higher than the surface resistance or polarization offered to copper deposition onto the nucleation layer, copper plating is preferentially directed onto the unsuppressed surface of the nucleation layer 111 at the openings area 114 (FIG. 4). This is a self-healing mechanism that automatically fixes the openings 114 in the plated copper layer. Once the exposed surfaces of the nucleation layer 111 are covered with copper, copper deposition may properly commence over the whole copper covered internal trench 100 surfaces and other surfaces covered with copper since the additive adsorbs equally and uniformly on all these surfaces. It will be understood that this process may also be used to repair openings in a seed layer. FIG. 4 illustrates, in partial view, a transition stage where a transition copper layer 116′ patches the openings area 114 on the side wall 108, and the layer 116′ forms on the internal surface of the trench 100. As can be seen, more copper is deposited on the openings area 114 of the plated copper layer by the process of this embodiment. As the deposition continues on the transition layer 116′, the copper layer 116 fills the trench without holes or defects.

In another embodiment, the copper electrochemical deposition may be performed in two stages. In a first stage, a first process solution, including an electrolyte with an excess amount of suppressor and/or leveler molecules, may be used to form the transition layer 116′ (see FIG. 4) to patch the open area or openings 114. After the patching is completed, the first process solution is removed and a second process solution, having proper chemistry optimized for good gap fill, is used to fill the trench 100 with the copper layer 116, as shown in FIG. 3. For example, for the first step, a suppressor concentration of 6-20 ml/l may be used, whereas for the gap fill (second step), a lower concentration of 3 to less than 6 ml/l may be utilized. Also in the chemistry of the first step, there may not be a need to include an accelerator additive since this additive is only needed at the second step for gap fill. Accelerators include sulfur containing organic molecules, such as SPS. They are widely marketed by companies such as Enthone and Shipley. It should be noted that the first and second stages of this embodiment may be carried out in different plating machines or process modules. In this case, instead of changing the chemistry in the same module for the first and second stages of the process, the wafer is transferred from the first process module working with the first chemistry to a second process module working with the second chemistry. The first chemistry may be the one with increased suppressor species and the second chemistry may be the one containing a suppressor, an accelerator and other additive species (such as chlorine and levelers) necessary for good gap fill.

Although various preferred embodiments and the best mode have been described in detail above, those skilled in the art will readily appreciate that many modifications of the exemplary embodiment are possible without materially departing from the novel teachings and advantages of this invention.

I claim:

1. A method of electrodepositing a conductor to form a defect-free layer on a wafer surface including at least one cavity, wherein the wafer surface including the at least one cavity is lined with a continuous conductive film, the method comprising:
electrodepositing the conductor onto the continuous conductive film from a process solution including at least one inhibiting additive configured to adsorb strongly on the conductor and weakly on the continuous conductive film being electrodeposited, wherein electrodepositing the conductor forms a discontinuous layer exposing a surface portion of the continuous conductive film;
having a first concentration of the at least one inhibiting additive adsorbed on the discontinuous layer while having a second concentration of the at least one inhibiting additive adsorbed on the exposed surface portion of the continuous conductive film, wherein the first concentration is higher than the second concentration; and
continuing electrodepositing the conductor wherein the conductor electrodeposits on the surface portion of the continuous conductive film at a higher rate than on the discontinuous layer, thus forming a defect-free layer.

2. The method of claim 1, wherein the defect-free layer is a conformal layer lining the continuous conductive film.

3. The method of claim 1, further comprising electrodepositing onto the defect-free layer to fill the at least one cavity with the conductor.

4. The method of claim 3, further comprising continuing electrodepositing the conductor, wherein continuing electrodepositing is performed using an other process solution comprising an other additive.

5. The method of claim 4, wherein the other additive comprises accelerator molecules.

6. The method of claim 1, wherein the inhibiting additive comprises suppressor molecules.

7. The method of claim 1, wherein the continuous conductive film is a nucleation layer.

8. The method of claim 7, wherein the nucleation layer comprises ruthenium.

9. The method of claim 7, wherein the nucleation layer comprises a material selected from the group consisting of W, Mo, MoN, and WCN.

10. The method of claim 1, wherein the conductor is copper.

11. The method of claim 1, wherein the inhibiting additive comprises leveler molecules.

12. The method of claim 1, wherein the inhibiting additive comprises suppressor and leveler molecules.

13. A method of forming a defect-free conformal conductive layer coating a surface of a wafer surface including at least one cavity, the wafer surface including the at least one cavity being lined with a nucleation layer, the method comprising:
electrodepositing a conductive layer onto the nucleation layer, wherein the conductive layer partially exposes a portion of the nucleation layer;
applying a solution onto the conductive layer and the exposed portion of the nucleation layer, wherein the solution includes at least one additive configured to adsorb strongly on the conductive layer and weakly on the nucleation layer;
adsorbing a first concentration of the at least one additive on the conductive layer while adsorbing a second concentration of the at least one additive on the portion of the nucleation layer; and
electrodepositing a conductor on the conductive layer and the portion of the nucleation layer to form a defect-free conformal conductive layer thereon, wherein the conductor electrodeposits on the exposed portion of the nucleation layer at a higher rate than on the conductive layer.

14. The method of claim 13, further comprising depositing the nucleation layer onto the wafer surface including the at least one cavity using atomic layer deposition process prior to electrodepositing the conductive layer onto the nucleation layer.

15. The method of claim 13, wherein the first concentration of the at least one additive is higher than the second concentration of the at least one additive.

16. The method of claim 13, wherein the conductor is copper.

17. The method of claim 13, wherein the at least one additive comprises suppressor molecules.

18. The method of claim 13, wherein the at least one additive comprises leveler molecules.

19. The method of claim 13, wherein the at least one additive comprises leveler and suppressor molecules.

20. A method of electrodepositing a conductor on a wafer surface having at least one cavity, wherein the wafer surface is lined with a nucleation layer, the method comprising electrodepositing a conductive layer on the nucleation layer, wherein electrodepositing comprises applying a solution to the wafer surface and the solution comprises at least one suppressor or leveler configured to adsorb strongly on material of the conductive layer and weakly on material of the nucleation layer.

21. The method of claim 20, wherein electrodepositing on any exposed portion of the nucleation layer takes place at a higher rate than electrodepositing on the conductive layer.

22. The method of claim 21, wherein a first concentration of the at least one suppressor or leveler on the conductive layer is higher than a second concentration of the at least one suppressor or leveler on any exposed portion of the nucleation layer.

23. The method of claim 20, wherein the at least one suppressor or leveler comprises suppressor molecules.

24. The method of claim 20, wherein the at least one suppressor or leveler comprises leveler molecules.
